(19) United States
(12) Patent Application Publication
(10) Pub. No.: US 2004/0043148 A1
(43) Pub. Date: Mar. 4, 2004

(54) Method for fabricating carbon nanotube device

(75) Inventors: Jeng-Hua Wei, Taipei (TW); Hung-Hsiang Wang, Taipei (TW); Ming-Jer Kao, Tainan (TW)

Correspondence Address: BACON & THOMAS, PLLC, 625 SLATERS LANE, FOURTH FLOOR, ALEXANDRIA, VA, 22314

(73) Assignee: Industrial Technology Research Institute, Chutung Hsinchu (TW)

(21) Appl. No.: 10/233,603

(22) Filed: Sep. 4, 2002

(51) Int. Cl. C23C 16/26

(52) U.S. Cl. 427/249.1; 427/255.7; 427/273; 427/301

(57) ABSTRACT

A method for fabricating a carbon nanotube device, characterized in that selective chemical vapor-phase deposition is performed on the lateral sides of the portion where the carbon nanotube device is to be formed defined by using the density of catalyst grains as well as etching technique so as to position the carbon nanotube device according to the arrangement of the catalyst grains. Therefore, the carbon nanotube device can be formed on a large-area chip can be achieved so as to further fabricate arrays of carbon nanotube memories and transistors.

### BACKGROUND OF THE INVENTION

1. Field of the Invention

The present invention generally relates to a method for fabricating a carbon nanotube device and, more particularly, to a method characterized in that selective chemical vapor-phase deposition is performed on the lateral side of the portion where the carbon nanotube device is to be formed defined by using the density of catalyst grains as well as etching technique so as to position the carbon nanotube device according to the arrangement of the catalyst grains.

2. Description of the Prior Art

In the nanotechnology era, it is required to fabricate a plurality of single cells, from bottom-up, in a large area. Therefore, it has become a major issue to efficiently fabricate nano-scale devices on a large area (typically larger than 1 cm²) so as to fulfill mass production based on research and development.

Richard Smalley et al. have disclosed a positioning technique of carbon nanotubes (Chemical Physics Letters 303 (1-2) pp. 125-129, 1999), in which AFM is employed to perform surface treatment such that different regions of the surface have different absorptivities associated with the carbon nanotubes. For example, carbon nanotubes are linked with NH₂ region on the surface while not linked with the CH₃ region such that the carbon nanotubes are arranged. However, AFM process has a low throughput and can not be applied to a large area.

Another conventional technique is disclosed by Charles Lieber et al., in which (Science 291, pp. 630) the variation in velocity and direction of fluid is employed to control the arrangement of carbon nanotubes deposited on the chip surface so that the carbon nanotubes can be arranged in the same orientation. However, in this method, the positioning of carbon nanotubes can not be consistent and other techniques have to be incorporated.

Y. S. Han et al. (Journal of Applied Physics Vol. 90, pp. 5731) has also disclosed a method for forming multi-walled nanotubes (MWNT's) by lateral growth. However, the density of the carbon nanotubes still can not be controlled.

Therefore, there is need in providing a method for fabricating a carbon nanotube device, in which the positioning of carbon nanotubes can be completed on a large-area chip by using conventional semiconductor manufacturing technology as well as selective chemical vapor-phase deposition.

### SUMMARY OF THE INVENTION

Accordingly, it is the primary object of the present invention to provide a method for fabricating a carbon nanotube device, characterized in that selective chemical vapor-phase deposition is performed on the lateral side of the portion where the carbon nanotube device is to be formed defined by using the density of catalyst grains as well as etching technique so as to position the carbon nanotube according to the arrangement of the catalyst grains.

It is the secondary object of the present invention to provide a method for fabricating a carbon nanotube device, characterized in that the method can be employed with conventional semiconductor manufacturing process so as to achieve mass production on a large-area chip.

In order to achieve the foregoing objects, the present invention provides a method for fabricating a carbon nanotube device, comprising steps of: depositing a plurality of nano-scale metal catalyst grains on a substrate; depositing a metal film covering said substrate and said plurality of nano-scale metal catalyst grains; performing etching on said metal film according to a pre-determined pattern so as to expose one of said nano-scale metal catalyst grains on one lateral side of said etched metal film; and forming a carbon nanotube from said exposed nano-scale metal catalyst grain by selective lateral growth in a deposition system.

The present invention further provides another method for fabricating a carbon nanotube device, comprising steps of: depositing a first metal film on a substrate; performing etching on said first metal film to have a pre-determined pattern; depositing an oxide film covering said substrate and said first metal film; depositing a plurality of nano-scale metal catalyst grains on said oxide film; depositing a second metal film covering said plurality of nano-scale metal catalyst grains; performing etching on said second metal film according to a pre-determined pattern; further performing etching on said second metal film according to another pre-determined pattern so as to expose one of said nano-scale metal catalyst grains on one lateral side of said etched second metal film; and forming a carbon nanotube from said exposed nano-scale metal catalyst grain by selective lateral growth in a deposition system.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms.

### BRIEF DESCRIPTION OF THE DRAWINGS

The objects, spirits and advantages of the preferred embodiments of the present invention will be readily understood by the accompanying drawings and detailed descriptions, wherein:

FIG. 1A is a schematic diagram showing a plurality of nano-scale metal catalyst grains deposited on a substrate in accordance with one preferred embodiment of the present invention;

FIG. 1B is a schematic diagram showing a metal film covering the substrate and the nano-scale metal catalyst grains in accordance with one preferred embodiment of the present invention;

FIG. 1C is a schematic diagram showing an etched metal film exposing a nano-scale metal catalyst grain on one lateral side of the etched metal film in accordance with one preferred embodiment of the present invention;

FIG. 1D is a schematic diagram showing a carbon nanotube from the exposed nano-scale metal catalyst grain by selective lateral growth in a deposition system in accordance with one preferred embodiment of the present invention;

FIG. 2A is a schematic diagram showing a first metal film deposited on a substrate in accordance with another preferred embodiment of the present invention;

FIG. 2B is a schematic diagram showing an etched first metal film with a pre-determined pattern in accordance with another preferred embodiment of the present invention;

FIG. 2C a schematic diagram showing an oxide film covering the substrate and the first metal film in accordance with another preferred embodiment of the present invention;

FIG. 2D a schematic diagram showing a plurality of nano-scale metal catalyst grains deposited on the oxide film in accordance with another preferred embodiment of the present invention;

FIG. 2E a schematic diagram showing a second metal film covering the nano-scale metal catalyst grains in accordance with another preferred embodiment of the present invention;

FIG. 2F a schematic diagram showing an etched second metal film with a pre-determined pattern in accordance with another preferred embodiment of the present invention;

FIG. 2G a schematic diagram showing a further etched second metal film exposing a nano-scale metal catalyst grain on one lateral side of the etched metal film in accordance with another preferred embodiment of the present invention; and

FIG. 2H is a schematic diagram showing a carbon nanotube from the exposed nano-scale metal catalyst grain by selective lateral growth in a deposition system in accordance with another preferred embodiment of the present invention.

### DETAILED DESCRIPTION OF THE INVENTION

The present invention providing a method for fabricating a carbon nanotube device can be exemplified by the preferred embodiments as described hereinafter.

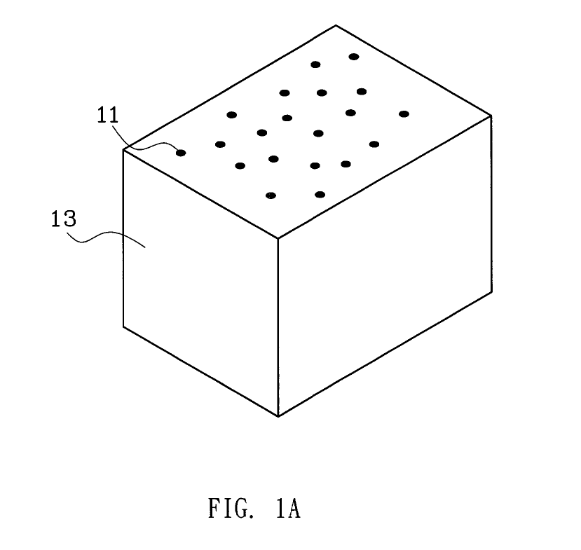

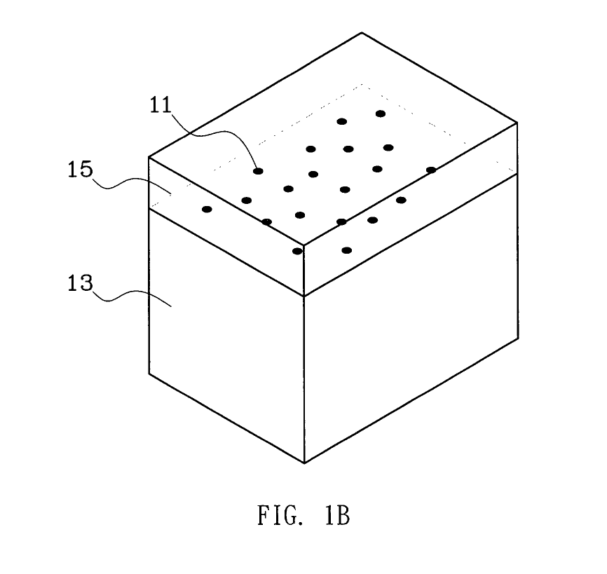

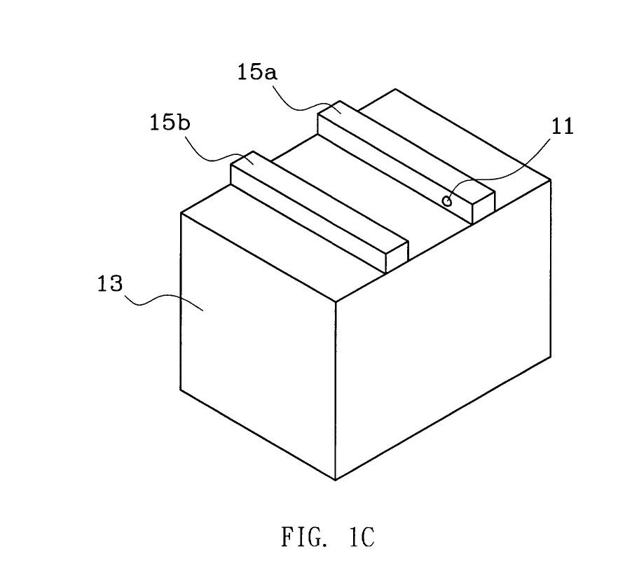

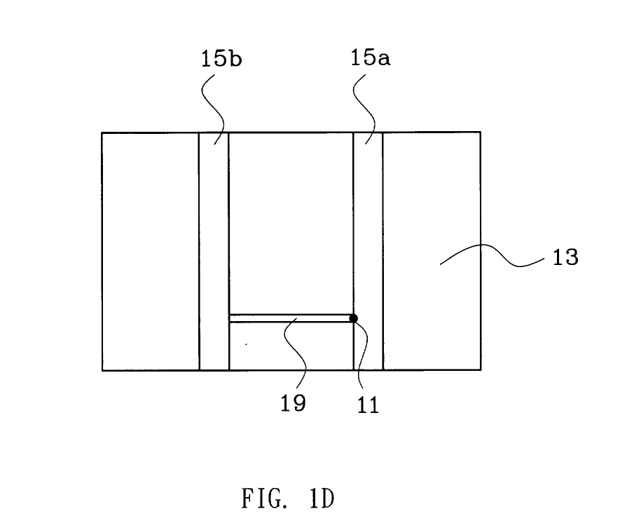

Please refer to FIG. 1A to FIG. 1D, which show a method for positioning and growing a carbon nanotube device in accordance with one preferred embodiment of the present invention. As shown in FIG. 1A, a plurality of nano-scale metal catalyst grains 11 are deposited on a substrate 13 formed of silicon dioxide. In the present invention, the metal catalyst grains 11 are randomly formed. The size and density of the catalyst grains 11 can be adjusted according to practical use.

Then, as shown in FIG. 1B, a metal film 15 is deposited on the substrate 13 to cover the substrate 13 and the nano-scale metal catalyst grains 11. Note that the material that forms the metal film 15 is different from the material that forms the nano-scale metal catalyst grains 11. It is essential that the metal film 15 does not affect the growth of carbon nanotubes after the metal film 15 contacts the nano-scale metal catalyst grains 11, even in a high-temperature environment.

Next, lithography by using a mask is employed to define a pattern. Etching is then performed on the metal film 15 according to the determined pattern so as to expose one of the nano-scale metal catalyst grains 11 on one lateral side of the etched metal film, including a first metal stripe 15a and a second metal stripe 15b, as shown in FIG. 1C. Afterwards, the rest of the nano-scale metal catalyst grains 11 that are not selected are later removed. Meanwhile, only one nano-scale metal catalyst grain 11 is left on the lateral side between the first metal stripe 15a and the second metal stripe 15b.

Then, the chip is placed in a deposition system that contains gaseous carbon so as to form a carbon nanotube 19 from the exposed nano-scale metal catalyst grain 11 by selective lateral growth, as shown in FIG. 1D. The carbon nanotube 19 grows from the first metal stripe 15a and finally stops when it reaches the second metal stripe 15b. Therefore, a carbon nanotube 19 is formed connecting the first metal stripe 15a and the second metal stripe 15b.

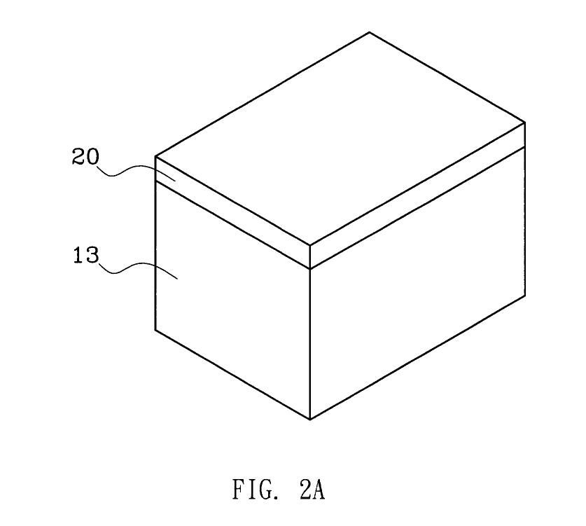

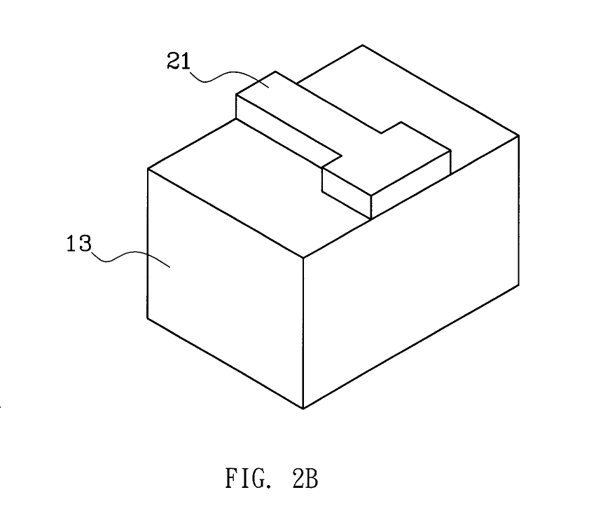

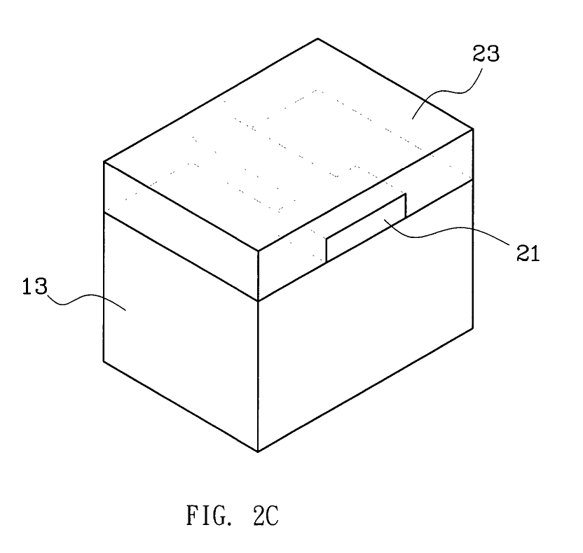

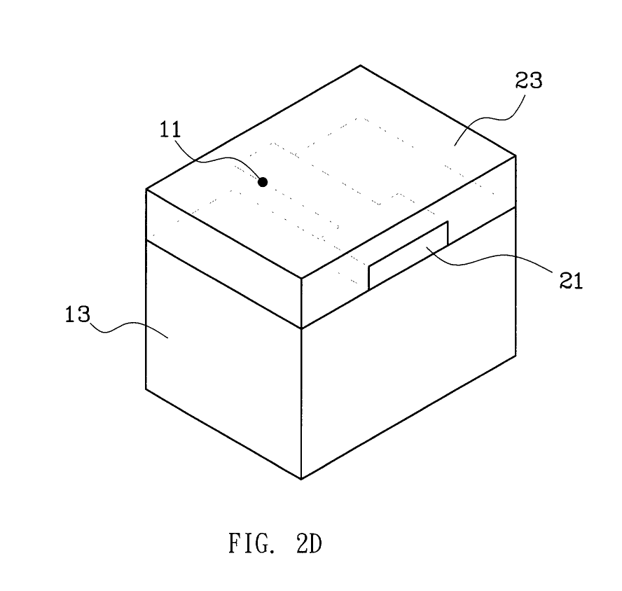

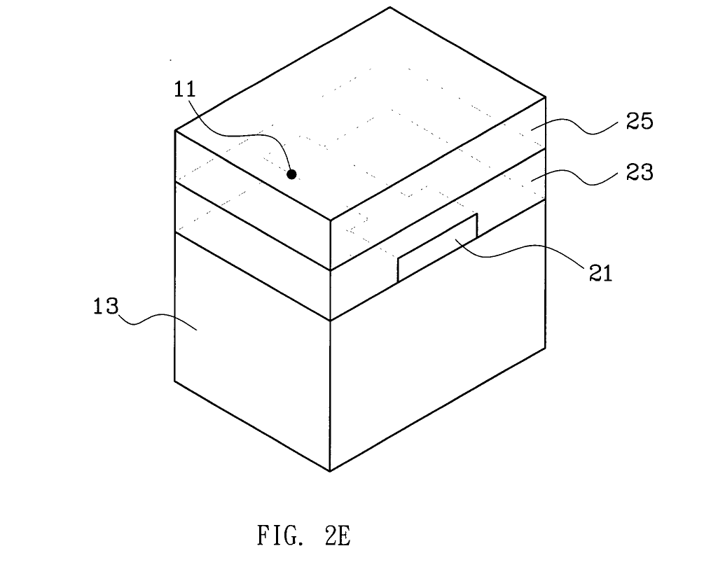

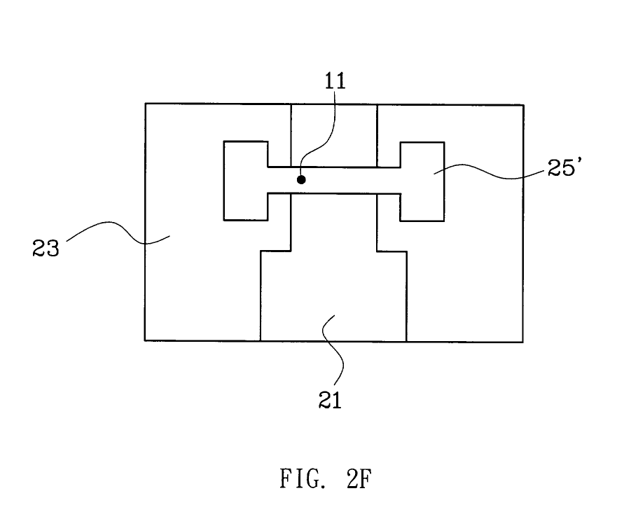

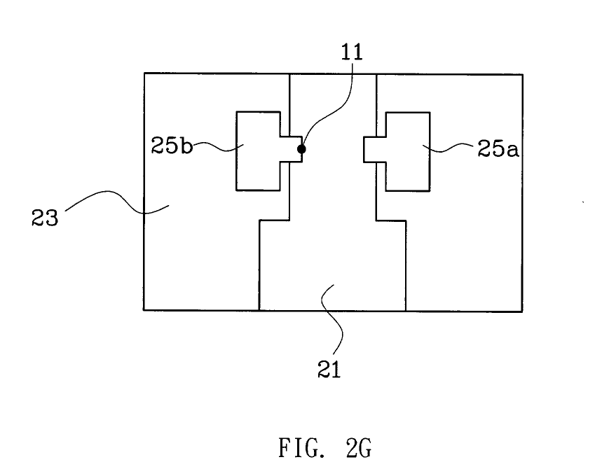

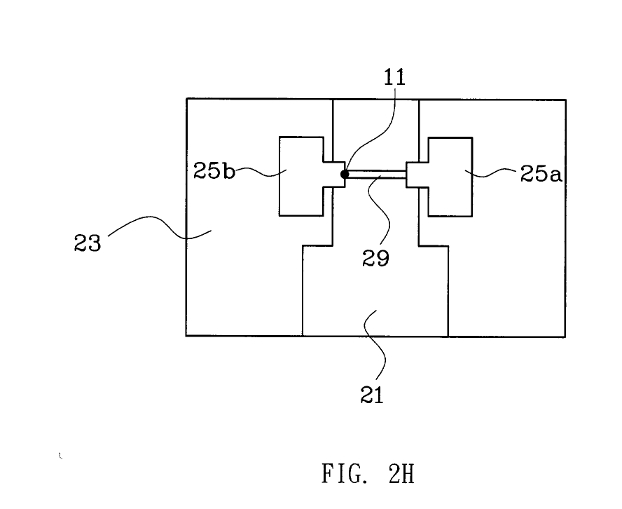

The present invention further discloses another embodiment as shown in FIG. 2A to FIG. 2H, which show a method for positioning and growing a carbon nanotube device. As shown in FIG. 2A, a first metal film 20 is deposited on a substrate 13 formed of silicon dioxide. In the present invention, the substrate 13 can also be formed of a polymer. Later, a photoresist film is deposited on the first metal film 20 and is then patterned by using photolithography. Etching is later performed on the first metal film 20 so as to generate a pattern 21, as shown in FIG. 2B. Then, an oxide film 23 is deposited to cover the substrate 13 and the pattern 21 of the etched first metal film 20, as shown in FIG. 2C. In FIG. 2D, a plurality of nano-scale metal catalyst grains 11 are randomly deposited on the oxide film 23. The size and density of the catalyst grains 11 can be adjusted according to practical use.

Then, as shown in FIG. 2E, a second metal film 25 is deposited to cover the nano-scale metal catalyst grains 11. Note that the material that forms the second metal film 25 is different from the material that forms the nano-scale metal catalyst grains 11. It is essential that the second metal film 25 does not affect the growth of carbon nanotubes after the second metal film 25 contacts the nano-scale metal catalyst grains 11, even in a high-temperature environment.

Next, lithography by using a mask is employed to define a pattern. Etching is then performed on the second metal film 25 so as to form an etched second metal film 25′, as shown in FIG. 2F. Afterwards, most of the nano-scale metal catalyst grains 11 that are not selected are later removed. Meanwhile, the rest of nano-scale metal catalyst grain 11 are left inside or near the etched second metal film 25′.

Then, lithography by using a mask is employed to define another pattern. Etching is further performed on the etched second metal film 25′ so as to expose one of the nano-scale metal catalyst grains 11 on one lateral side of the etched second metal film 25′, including a first metal mallet 25a and a second metal mallet 25b, as shown in FIG. 2G. Meanwhile, only one nano-scale metal catalyst grain 11 is left on the lateral side between the first metal mallet 25a and the second metal mallet 25b.

Finally, the chip is placed in a deposition system that contains gaseous carbon so as to form a carbon nanotube 29 from the exposed nano-scale metal catalyst grain 11 by selective lateral growth, as shown in FIG. 2H. The carbon nanotube 29 grows from the second metal mallet 25b and finally stops when it reaches the first metal mallet 25b. Therefore, a carbon nanotube 19 is formed connecting the first metal mallet 25a and the second metal mallet 25b.

Accordingly, the method for fabricating a carbon nanotube device according to the present invention can also be used to form a nano-scale metal catalyst grain 11 on any lateral side of the carbon nanotube device. In addition, the diameter of the carbon nanotube is proportional to the size of the nano-scale metal catalyst grain, therefore, the present invention employs lateral growth according to the size of the nano-scale metal catalyst grain so as to determine the diameter of the carbon nanotube, for example 2˜3 nm for a single-walled nanotube (SWNT) and larger size for a multi-walled nanotube (MWNT). In other words, the present invention can be used to position and form carbon nanotubes on a large-area chip by using conventional semiconductor manufacturing technology as well as selective chemical vapor-phase deposition. Moreover, the density of size of the nano-scale metal catalyst grains can be determine to control the diameter and arrangement of the carbon nanotubes.

To sum up, the present invention is characterized in that:

(1) the density and the size of the nano-scale metal catalyst grains can be adjusted;

(2) the arrangement of the carbon nanotube on the substrate can be controlled by determining the position of the nano-scale metal catalyst grains;

(3) The carbon nanotube can be formed in parallel with the substrate surface by using selective lateral growth on the lateral side of the portion where the carbon nanotube device is to be formed;

(4) the diameter of the carbon nanotube can be controlled by determining the diameter of the metal catalyst grain;

(5) whether a single-walled nanotube (SWNT) or a multi-walled nanotube (MWNT) is to be grown depends on the diameter of the metal catalyst grain;

(6) the density of the carbon nanotubes depends on the density of the nano-scale metal catalyst grains; and

(7) the nano-scale metal catalyst grains contact the metal film directly so that there is provided a good ohmic contact.

According to the above discussion, it is apparent that the present invention discloses a method for fabricating a carbon nanotube device, characterized in that selective chemical vapor-phase deposition is performed on the lateral sides of the portion where the carbon nanotube device is to be formed defined by using the density of catalyst grains as well as etching technique so as to position the carbon nanotube device according to the arrangement of the catalyst grains. Therefore, the present invention has been examined to be progressive, advantageous and applicable to the industry.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A method for fabricating a carbon nanotube device, comprising steps of:
depositing a plurality of nano-scale metal catalyst grains on a substrate;
depositing a metal film covering said substrate and said plurality of nano-scale metal catalyst grains;
performing etching on said metal film according to a pre-determined pattern so as to expose one of said nano-scale metal catalyst grains on one lateral side of said etched metal film; and
forming a carbon nanotube from said exposed nano-scale metal catalyst grain by selective lateral growth in a deposition system.

2. The method for fabricating a carbon nanotube device as claimed in claim 1, wherein the material that forms said metal film is different from the material that forms said nano-scale metal catalyst grains.

3. The method for fabricating a carbon nanotube device as claimed in claim 1, wherein the carbon element in said carbon nanotube comes from the gaseous carbon in said deposition system.

4. The method for fabricating a carbon nanotube device as claimed in claim 1, wherein said metal film contacts said nano-scale metal catalyst grains.

5. The method for fabricating a carbon nanotube device as claimed in claim 1, wherein said carbon nanotube connects a first metal stripe and a second metal stripe.

6. A method for fabricating a carbon nanotube device, comprising steps of:
depositing a first metal film on a substrate;
performing etching on said first metal film to have a pre-determined pattern;
depositing an oxide film covering said substrate and said first metal film;
depositing a plurality of nano-scale metal catalyst grains on said oxide film;
depositing a second metal film covering said plurality of nano-scale metal catalyst grains;
performing etching on said second metal film according to a pre-determined pattern;
further performing etching on said second metal film according to another pre-determined pattern so as to expose one of said nano-scale metal catalyst grains on one lateral side of said etched second metal film; and
forming a carbon nanotube from said exposed nano-scale metal catalyst grain by selective lateral growth in a deposition system.

7. The method for fabricating a carbon nanotube device as claimed in claim 6, wherein the material that forms said first metal film is different from the material that forms said nano-scale metal catalyst grains.

8. The method for fabricating a carbon nanotube device as claimed in claim 6, wherein the carbon element in said carbon nanotube comes from the gaseous carbon in said deposition system.

9. The method for fabricating a carbon nanotube device as claimed in claim 6, wherein said second metal film contacts said nano-scale metal catalyst grains.

10. The method for fabricating a carbon nanotube device as claimed in claim 6, wherein said carbon nanotube connects a first metal mallet and a second metal mallet.
